(19) United States
(12) Patent Application Publication
(10) Pub. No.: US 2024/0021591 A1
(43) Pub. Date: Jan. 18, 2024

(54) SEMICONDUCTOR PACKAGE

(71) Applicant: SAMSUNG ELECTRONICS CO., LTD., Suwon-si (KR)

(72) Inventor: Taeyoung LEE, Suwon-si (KR)

(21) Appl. No.: 18/217,655

(22) Filed: Jul. 3, 2023

(30) Foreign Application Priority Data
Jul. 14, 2022 (KR) 10-2022-0086846

(51) Int. Cl. H01L 25/10; H01L 23/31; H01L 23/00; H01L 23/538; H01L 23/498

(52) U.S. Cl. CPC H01L 25/105; H01L 23/3135; H01L 24/32; H01L 23/5384; H01L 23/49822; H01L 24/16; H01L 24/08; H01L 2924/1436; H01L 2224/08148; H01L 2224/32245; H01L 2924/1438; H01L 2224/32225; H01L 2224/16238; H01L 2224/16148; H01L 2224/08238; H01L 2224/16227

(57) ABSTRACT

A semiconductor package may include: a substrate; an upper chip disposed on the substrate; a first lower semiconductor chip disposed between the substrate and the upper chip, and electrically connected to the substrate; a second lower semiconductor chip disposed between the substrate and the upper chip, and electrically connected to the substrate; and an interposer chip disposed between the substrate and the upper chip, wherein the interposer chip includes a through-via electrically connecting the upper chip to the substrate, wherein the first lower semiconductor chip is electrically connected to the upper chip, wherein a lower surface of the upper chip is disposed on an upper surface of the first lower semiconductor chip, and wherein the second lower semiconductor chip is electrically connected to the upper chip, wherein a lower surface of the upper chip is disposed on an upper surface of the second lower semiconductor chip.

### CROSS-REFERENCE TO RELATED APPLICATION

This application is based on and claims priority under 35 U.S.C. § 119 to Korean Patent Application No. 10-2022-0086846, filed on Jul. 14, 2022, with the Korean Intellectual Property Office, the disclosure of which is incorporated by reference herein in its entirety.

### TECHNICAL FIELD

The present inventive concept relates to a semiconductor package.

### DISCUSSION OF THE RELATED ART

Generally, semiconductor devices included in electronic devices are relatively small in size and have relatively high performance and relatively high capacity. To implement this, a system-in-package (SiP) technology for interconnecting heterogeneous semiconductor chips in a single semiconductor package is under development.

### SUMMARY

An aspect of the present inventive concept is to provide a semiconductor package having increased reliability.

According to an example embodiment of the present inventive concept, a semiconductor package includes: a substrate; a first lower semiconductor chip including a first front pad and a first rear pad, opposing each other, a first circuit region disposed between the first front pad and the first rear pad, and a first lower through-via electrically connecting the first rear pad to a first integrated circuit of the first circuit region, wherein the first integrated circuit is electrically connected to the first front pad, wherein the first lower semiconductor chip is disposed on the substrate so that the first front pad or the first rear pad faces in an upward direction; a second lower semiconductor chip including a second front pad and a second rear pad, opposing each other, a second circuit region disposed between the second front pad and the second rear pad, and a second lower through-via electrically connecting the second rear pad to a second integrated circuit of the second circuit region, wherein the second integrated circuit is electrically connected to the second front pad, wherein the second lower semiconductor chip is disposed on the substrate so that the second front pad or the second rear pad faces in the upward direction; an interposer chip including a third front pad and a third rear pad, opposing each other, and a third lower through-via electrically connecting the third front pad and the third rear pad to each other, wherein the interposer chip is disposed between the first lower semiconductor chip and the second lower semiconductor chip so that the third front pad or the third rear pad faces in the upward direction, and is disposed on the substrate; and an upper chip disposed on the first lower semiconductor chip, the second lower semiconductor chip, and the interposer chip, wherein the upper chip includes first connection pads in contact with the first front pad or the first rear pad facing in the upward direction, the second front pad or the second rear pad facing in the upward direction, and the third front pad or the third rear pad facing in the upward direction.

According to an example embodiment of the present inventive concept, a semiconductor package includes: a substrate including an interconnection structure; an upper chip disposed on the substrate, wherein the upper chip includes first connection pads; a first lower semiconductor chip disposed between the substrate and the upper chip, wherein the first lower semiconductor chip includes a first rear pad and a first front pad, wherein the first rear pad is connected to the first connection pads, and the first front pad is connected to the interconnection structure; a second lower semiconductor chip disposed between the substrate and the upper chip, wherein the second lower semiconductor chip includes a second rear pad and a second front pad, wherein the second rear pad is connected to the first connection pads, and the second front pad is connected to the interconnection structure; an interposer chip disposed between the substrate and the upper chip, wherein the interposer chip includes a lower through-via electrically connecting the first connection pads of the upper chip to the interconnection structure of the substrate; and a chip structure disposed on the substrate and adjacent to the second lower semiconductor chip, and electrically connected to the second lower semiconductor chip through the interconnection structure.

According to an example embodiment of the present inventive concept, a semiconductor package includes: a substrate; an upper chip disposed on the substrate; a first lower semiconductor chip disposed between the substrate and the upper chip, and electrically connected to the substrate; a second lower semiconductor chip disposed between the substrate and the upper chip, and electrically connected to the substrate; and an interposer chip disposed between the substrate and the upper chip, wherein the interposer chip includes a through-via electrically connecting the upper chip and the substrate to each other, wherein the first lower semiconductor chip is electrically connected to the upper chip, wherein a lower surface of the upper chip is disposed on an upper surface of the first lower semiconductor chip, and wherein the second lower semiconductor chip is electrically connected to the upper chip, wherein a lower surface of the upper chip is disposed on an upper surface of the second lower semiconductor chip.

### BRIEF DESCRIPTION OF DRAWINGS

The above and other aspects of the present inventive concept will become more apparent by describing in detail example embodiments thereof, with reference to the accompanying drawings, in which:

FIG. 1A is a plan view illustrating a semiconductor package according to an example embodiment of the present inventive concept;

FIG. 1B is a plan view illustrating a semiconductor package according to an example embodiment of the present inventive concept;

FIG. 2A is a cross-sectional view taken along the line I-I′ of FIGS. 1A and 1B;

FIG. 2B is a partially enlarged view illustrating region ‘A’ of FIG. 2A;

FIG. 2C is a partially enlarged view illustrating region ‘B’ of FIG. 2A;

FIG. 2D is a partially enlarged view illustrating region ‘C’ of FIG. 2A;

FIG. 2E is a partially enlarged view illustrating region ‘D’ of FIG. 2D;

FIG. 3 is a cross-sectional view illustrating a semiconductor package according to an example embodiment of the present inventive concept;

FIG. 4 is a cross-sectional view illustrating a semiconductor package according to an example embodiment of the present inventive concept;

FIG. 5 is a cross-sectional view illustrating a semiconductor package according to an example embodiment of the present inventive concept;

FIG. 6 is a cross-sectional view illustrating a semiconductor package according to an example embodiment of the present inventive concept; and

FIGS. 7A and 7B are cross-sectional views sequentially illustrating manufacturing processes of a method of manufacturing the semiconductor package of FIG. 2A according to an example embodiment of the present inventive concept.

### DETAILED DESCRIPTION OF THE EMBODIMENTS

Hereinafter, example embodiments of the present inventive concept will be described with reference to the accompanying drawings as follows.

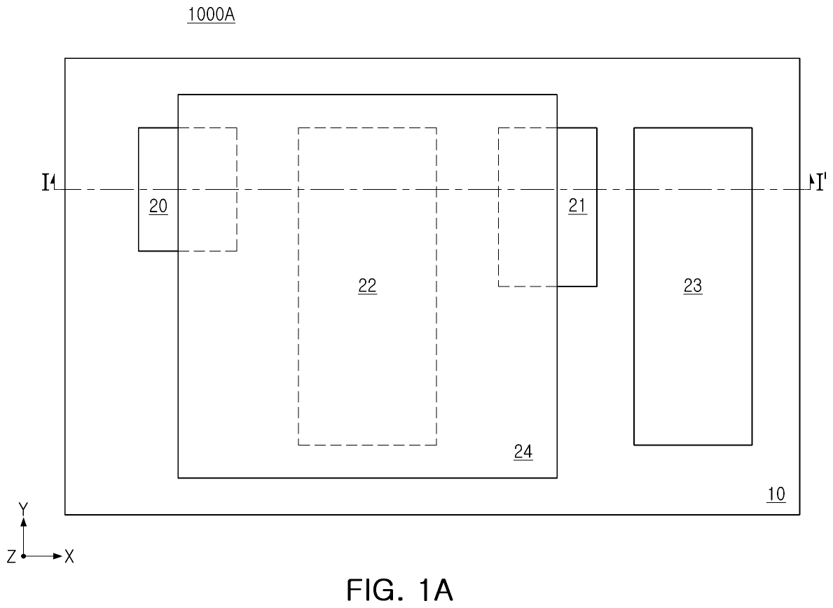

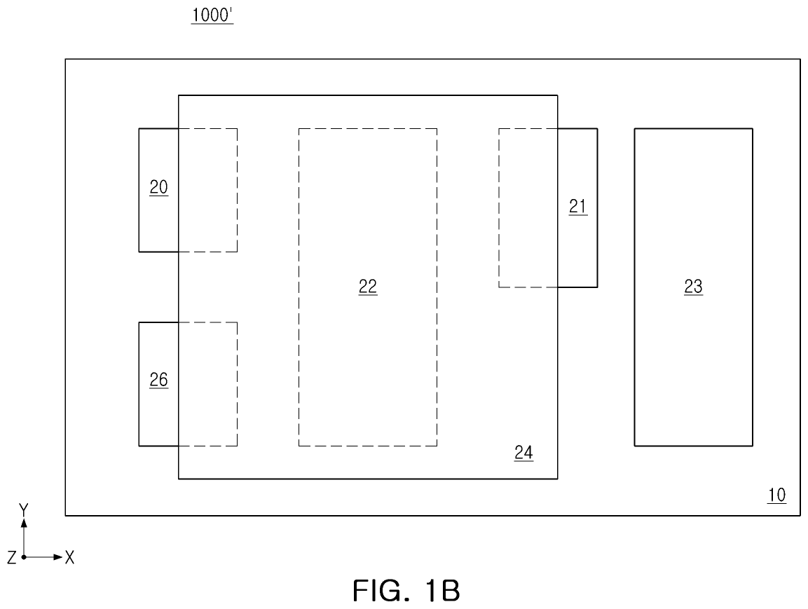

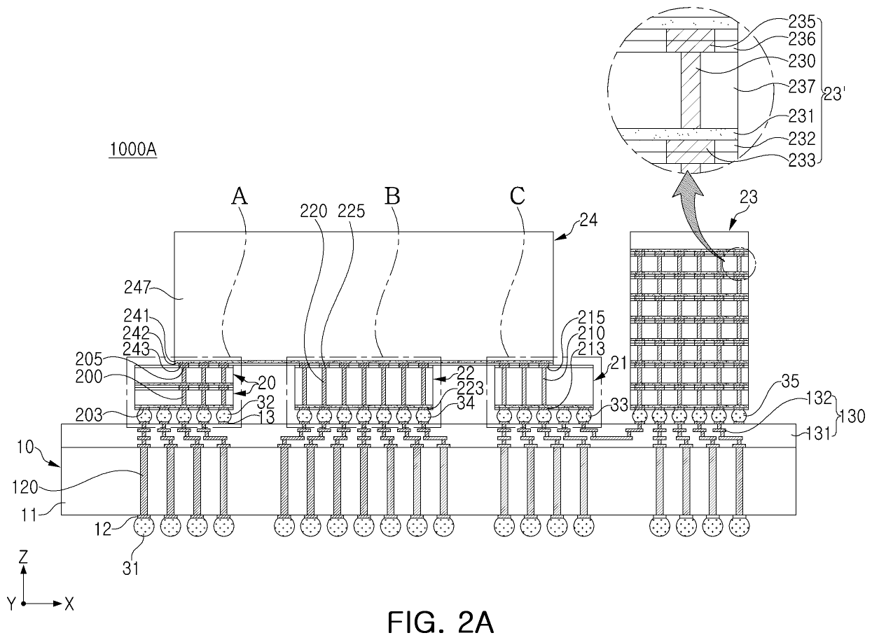

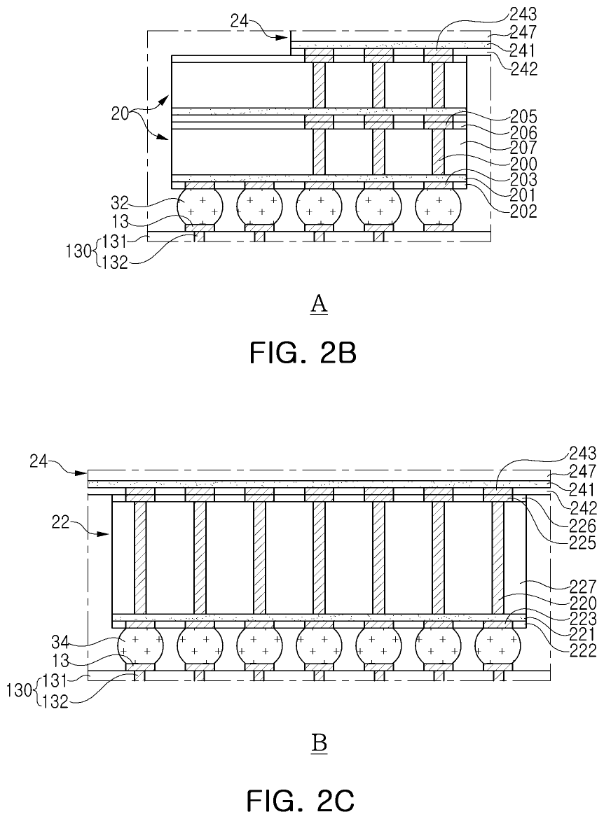

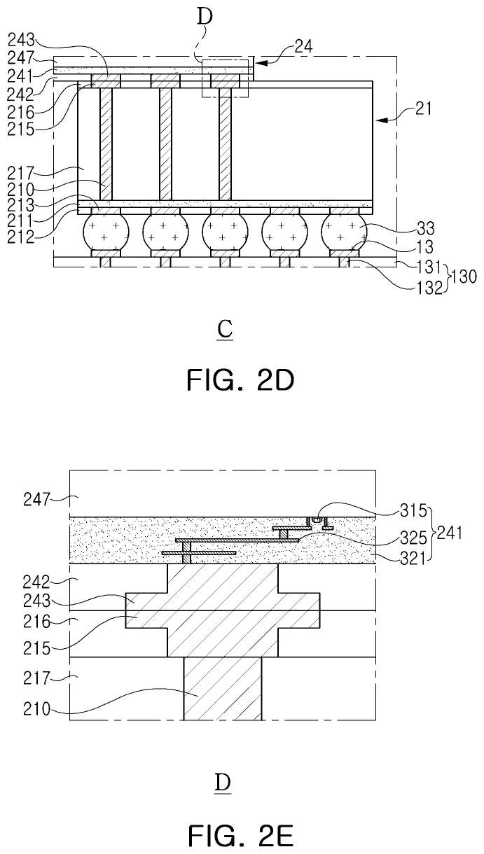

FIG. 1A is a plan view illustrating a semiconductor package 1000A according to an example embodiment of the present inventive concept. FIG. 1B is a plan view illustrating a semiconductor package 1000′ according to an example embodiment of the present inventive concept. FIG. 2A is a cross-sectional view taken along the line I-I′ of FIGS. 1A and 1B. FIG. 2B is a partially enlarged view illustrating region ‘A’ of FIG. 2A. FIG. 2C is a partially enlarged view illustrating region ‘B’ of FIG. 2A. FIG. 2D is a partially enlarged view illustrating region ‘C’ of FIG. 2A. FIG. 2E is a partially enlarged view illustrating region ‘D’ of FIG. 2D.

Referring to FIGS. 1A to 2E, the semiconductor package 1000A may include a substrate 10, an upper chip 24, a first lower semiconductor chip 20, a second lower semiconductor chip 21, and an interposer chip 22. In addition, the semiconductor package 1000A may further include a chip structure 23, a lower connection bump 31, and first to fourth intermediate connection bumps 32, 33, 34, and 35.

The substrate 10 may include a substrate body 11, connection pads 12 and 13 disposed on a lower surface and an upper surface of the substrate body 11, a substrate through-via 120 and an interconnection region 130. For example, the first surface of the substrate body 11 may be referred to as a lower surface, and the second surface of the substrate body 11 may be referred to as an upper surface; however, the present inventive concept is not limited thereto.

The substrate body 11 may have the lower surface and the upper surface, opposite to the lower surface. The substrate body 11 may include different materials depending on the type of the substrate 10. For example, when the substrate 10 is a printed circuit board, the substrate body 11 may have a form in which an interconnection layer is additionally laminated on one or both sides of a body copper clad laminate or a copper clad laminate. For example, a protective layer protecting connection pads 12 and 13 may be formed on the lower and upper surfaces of the substrate body 11. For example, the substrate body 11 may be a semiconductor wafer. The substrate body 11 may include a semiconductor element such as silicon, germanium, or a compound semiconductor such as silicon carbide (SiC), gallium arsenide (GaAs), indium arsenide (InAs), and indium phosphide (InP). For example, the lower or upper surface of the substrate body 11 may be covered with an insulating film formed of a silicon oxide film, a silicon nitride film, or a combination thereof.

Connection pads 12 and 13 in contact with the plurality of connection bumps 31, 32, 33, 34, and 35 may be disposed on the lower surface and upper surface of the substrate 10. For example, the connection pads 12 and 13 may be buried in the lower and upper surfaces of the substrate 10. In this case, side surfaces of the connection pads 12 and 13 may be surrounded by an insulating film formed of, for example, a silicon oxide film, a silicon nitride film, or a combination thereof. The connection pads 12 and 13 may include a metallic material, for example, at least one metal of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C) or an alloy containing two or more metals thereof.

The substrate through-via 120 may be a through silicon via (TSV) penetrating through the substrate body 11 in a vertical direction (e.g., a Z-direction). The through-substrate via 120 may penetrate through the substrate body 11 to electrically connect the lower connection bump 31 disposed on the lower surface of the substrate body 11 and the interconnection structure 132 to each other. For example, the substrate through-via 120 may form an electrical path connecting the connection pads 12 and 13 on the lower surface and the upper surface of the substrate 10. The through-substrate via 120 may include a conductive plug and a barrier film surrounding the conductive plug. The conductive plug may include a metal material, for example, tungsten (W), titanium (Ti), aluminum (Al), or copper (Cu). The conductive plug may be formed by a plating process, a PVD process, or a CVD process. The barrier film may include, for example, titanium (Ti), titanium nitride (TiN), tantalum (Ta), or tantalum nitride (TaN), and may be formed by a plating process, a PVD process, or a CVD process. A side insulating film including an insulating material (e.g., high aspect ratio process (HARP) oxide) such as silicon oxide, silicon nitride, or silicon oxynitride may be formed between the through-substrate via 120 and the substrate body 11.

The interconnection region 130 may be disposed on a second surface of the substrate body 11, and may include an interconnection structure 132 and an interlayer insulating layer 131.

The interconnection structure 132 may interconnect the second lower semiconductor chip 21 and the chip structure 23 to each other, or connects the plurality of chips 20, 21, 22, 23, and 24 to an external device (e.g., a main board, a motherboard, etc.) through the lower connection bump 31. The interconnection structure 132 may include one or more layers of metal interconnections and contact vias. The contact via may connect the metal interconnections to each other or the metal interconnections to the connection pad 13. The interconnection structure 132 may electrically and physically connect the through-substrate via 120 and the connection pad 13 to each other.

The interlayer insulating layer 131 may surround the interconnection structure 132 and may be disposed on the upper surface of the substrate body 11. The interlayer insulating layer 131 may include, for example, Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), and Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or a combination thereof. At least a portion of the interlayer insulating layer 131 surrounding the interconnection structure 132 may be configured as a low-K layer. The interlayer insulating layer 131 may be formed using, for example, a chemical vapor deposition (CVD) process, a flowable-CVD process, or a spin coating process.

The upper chip 24 may be disposed on the substrate 10, and may include an upper chip body 247, a circuit region 241 of the upper chip 24, first connection pads 243, and a first connection pad insulating layer 242.

The upper chip 24 may be disposed on the first lower semiconductor chip 20, the second lower semiconductor chip 21, and the interposer chip 22.

The upper chip 24 may overlap at least a portion of each of the first lower semiconductor chip 20, the second lower semiconductor chip 21, and the interposer chip 22 in a direction (e.g., the Z-direction) substantially perpendicular to the upper surface of the substrate 10.

The upper chip 24 may be a logic chip including, for example, a central processor (CPU), a graphics processor (GPU), a field programmable gate array (FPGA), a digital signal processor (DSP), an encryption processor, a microprocessor, a microcontroller, an application specific integrated circuit (ASIC), and the like. For example, the upper chip 24 may include an application processor (AP).

The upper chip body 247 may be a semiconductor wafer substrate having a front surface and a rear surface, facing each other. For example, the upper chip body 247 may be a semiconductor wafer including a semiconductor element such as silicon and germanium, or a compound semiconductor such as silicon carbide (SiC), gallium arsenide (GaAs), indium arsenide (InAs), and indium phosphide (InP). The front surface thereof may be an active surface doped with impurities, and the rear surface thereof may be an inactive surface opposite to the front surface.

As illustrated in FIG. 2E, the circuit region 241 of the upper chip 24 may be on the upper chip 24, and may include an interconnection structure 325 connected to the active region and a protective layer 321 surrounding the same. For example, the circuit region 241 may be disposed on the front surface or active surface of the upper chip 24. As another example, the circuit region 241 may be disposed on a lower surface of the upper chip 24.

The protective layer 321 may include, for example, Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), and Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or a combination thereof. At least a portion of the protective layer 321 surrounding the interconnection structure 325 may be configured as a low-x layer. The protective layer 321 may be formed using, for example, a chemical vapor deposition (CVD) process, a flowable-CVD process, or a spin coating process.

The interconnection structure 325 may be formed of a multilayer structure including an interconnection pattern including, for example, aluminum (Al), gold (Au), cobalt (Co), copper (Cu), nickel (Ni), lead (Pb), tantalum (Ta), or tellurium (Te), titanium (Ti), tungsten (W), or a combination thereof and vias. A barrier film including titanium (Ti), titanium nitride (TiN), tantalum (Ta), or tantalum nitride (TaN) may be disposed between the interconnection pattern or/and the vias and the protective layer 321. Individual devices 315 constituting an integrated circuit in combination with the interconnection structure 325 may be disposed on a front surface of the upper chip 24. The integrated circuit may include, for example, a logic circuit for the logic chip described above. In an example embodiment of the present inventive concept, the individual devices 315 constituting the integrated circuit in combination with the interconnection structure 325 may be disposed on the lower surface of the upper chip 24.

The first connection pads 243 may contact any one of the first front pad 203 or the first rear pad 205 facing in an upward direction. For example, as illustrated in FIG. 2B, the first connection pads 243 may be in direct contact with the first rear pad 205 facing in the upward direction.

The first connection pads 243 may contact any one of the second front pad 213 or the second rear pad 215 facing in the upward direction. For example, as illustrated in FIG. 2D, the first connection pads 243 may be in direct contact with the second rear pad 215 facing in the upward direction.

The first connection pads 243 may contact any one of the third front pad 223 or the third rear pad 225 facing in the upward direction. For example, as illustrated in FIG. 2C, the first connection pads 243 may be in direct contact with the third rear pad 225 facing in the upward direction.

For example, the first lower semiconductor chip 20, the second lower semiconductor chip 21, and the interposer chip 22 may be bonded to the upper chip 24 so that an upper surface of the first lower semiconductor chip 20, an upper surface of the second lower semiconductor chip 21, and an upper surface of the interposer chip 22 are directly bonded and bonded (e.g., may be referred to as hybrid bonding, direct bonding, or the like) without a connection member, such as a metal bump, or the like to a lower surface of the upper chip 24. Accordingly, the upper chip 24 may be electrically connected to the first lower semiconductor chip 20 and the second lower semiconductor chip 21. In addition, the upper chip 24 may be electrically connected to the substrate 10 through a third lower through-via 220 of the interposer chip 22.

The first connection pad insulating layer 242 may be disposed below the circuit region 241 of the upper chip 24 to surround the first connection pads 243. The first connection pad insulating layer 242 may include an insulating material that may be bonded and coupled to the second rear pad insulating layer 216 of the second lower semiconductor chip 21. For example, the first connection pad insulating layer 242 may include silicon oxide (SiO) or silicon carbonitride (SiCN). For example, at least a portion of the first connection pad insulating layer 242 may be bonded to the second rear pad insulating layer 216, so that the upper chip 24 and the second lower semiconductor chip 21 may be bonded and coupled to each other.

The first lower semiconductor chip 20 may be disposed on the substrate 10, and may include a circuit region 201, a first front pad 203, a first rear pad 205, and a first lower through-via 200. As illustrated in FIG. 2B, the first lower semiconductor chip 20 may further include a first front pad insulating layer 202, a first rear pad insulating layer 206, and a first lower semiconductor chip body 207.

The first lower semiconductor chip 20 may be disposed between the substrate 10 and the upper chip 24, and may be electrically connected to the substrate 10.

The first lower semiconductor chip 20 may include a first front pad 203 and a first rear pad 205, opposing each other, a first circuit region 201 disposed between the first front pad 203 and the first rear pad 205 and including a first integrated circuit electrically connected to the first front pad 203, and a first lower through-via 200 electrically connecting the first rear pad 205 to the first integrated circuit. The first lower semiconductor chip 20 may be disposed on the substrate 10 so that the first front pad 203 or the first rear pad 205 faces upwardly. In the present specification, the first circuit region 201 may be referred to as a circuit region 201 of the first lower semiconductor chip 20.

The first lower semiconductor chip 20 may be disposed between the substrate 10 and the upper chip 24, and may include a first rear pad 205, which is connected to the first connection pads 243, and a first front pad 203, which connected to the first rear pad 205 and the interconnection structure 132.

The first lower semiconductor chip 20 may be provided as a plurality of first lower semiconductor chips 20 vertically stacked on the substrate 10, and each of the plurality of first lower semiconductor chips 20 may be connected to each other through the first lower through-via 200.

The first lower semiconductor chip 20 may be disposed on the interconnection region 130.

The first lower semiconductor chip 20 may be disposed so that the first rear pad 205 faces upwardly.

The first lower semiconductor chip 20 may be electrically connected to the upper chip 24 between an upper surface of the first lower semiconductor chip 20 and a lower surface of the upper chip 24. The first lower semiconductor chip 20 may include, for example, a volatile memory such as dynamic RAM (DRAM), static RAM (SRAM), and the like, and a non-volatile memory such as phase change RAM (PRAM), magnetic RAM (MRAM), resistive RAM (RRAM), flash memory, and the like. For example, the first lower semiconductor chip 20 may include DRAM.

The circuit region 201 of the first lower semiconductor chip 20 may include the same or similar components to the circuit region 241 of the upper chip 24 described above. For example, the circuit region 201 of the first lower semiconductor chip 20 may include a first integrated circuit in which an interconnection structure 325 and individual devices 315 are combined. The first integrated circuit may be, for example, the memory circuit described above. For example, a cell structure constituting a memory circuit together with the individual devices 315 may be formed around the circuit region 201 of the first lower semiconductor chip 20. Depending on an example embodiment of the present inventive concept, the upper chip 24 may be electrically connected to the first integrated circuit through the first rear pad 205 and the first lower through-via 200.

Either of the first front pad 203 or the first rear pad 205 may be electrically connected to the interconnection structure 132.

The first front pad 203 and the first rear pad 205 may be buried in the lower surface and upper surface of the first lower semiconductor chip 20. In this case, a side surface of the first front pad 203 or the first rear pad 205 may be surrounded by an insulating film formed of, for example, a silicon oxide film, a silicon nitride film, or a combination thereof. The first front pad 203 or the first rear pad 205 may include a metal material, for example, at least one of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), carbon (C), or an alloy including two or more metals thereof.

It may be understood that the first lower through-via 200 has substantially the same characteristics as the above-described through-substrate via 120.

It may be understood that the first front pad insulating layer 202 and the first rear pad insulating layer 206 have substantially the same characteristics as the above-described first connection pad insulating layer 242.

It may be understood that the first lower semiconductor chip body 207 has substantially the same characteristics as the above-described upper chip body 247.

The second lower semiconductor chip 21 may be disposed on the substrate 10, and may include a circuit region 211, a second front pad 213, a second rear pad 215, and a second lower through-via 210. As illustrated in FIG. 2D, the second lower semiconductor chip 21 may further include a second front pad insulating layer 212, a second rear pad insulating layer 216, and a second lower semiconductor chip body 217.

The second lower semiconductor chip 21 may be disposed between the substrate 10 and the upper chip 24, and may be electrically connected to the substrate 10.

The second lower semiconductor chip 21 may include a second front pad 213 and a second rear pad 215, opposing each other, a second circuit region 211 disposed between the second front pad 213 and the second rear pad 215 and including a second integrated circuit electrically connected to the second front pad 213, and a second lower through-via 210 electrically connecting the second rear pad 215 to the second integrated circuit. The second lower semiconductor chip 21 may be disposed on the substrate 10 so that the second front pad 213 or the second rear pad 215 faces upwardly. In the present specification, the second circuit region 211 may be referred to as a circuit region 211 of the second lower semiconductor chip 21.

The second lower semiconductor chip 21 may be disposed between the substrate 10 and the upper chip 24, and may include a second rear pad 215 connected to the first connection pads 243 and a second front pad 213 connected to the interconnection structure 132.

The second lower semiconductor chip 21 may be electrically connected to the upper chip 24 between an upper surface of the second lower semiconductor chip 21 and a lower surface of the upper chip 24.

The second lower semiconductor chip 21 may be disposed so that the second rear pad 215 faces upwardly, and the upper chip 24 may be electrically connected to the second integrated circuit through the second rear pad 215 and the second lower through-via 210.

The second lower semiconductor chip 21 may be disposed on the interconnection region 130.

The second lower semiconductor chip 21 may be a memory controller configured to control a chip structure 23. For example, the chip structure 23 may include a NAND flash memory constituting the plurality of memory chips 23′, and the second lower semiconductor chip 21 may be a NAND controller.

The circuit region 211 of the second lower semiconductor chip 21 may include the same or similar components to the circuit region 241 of the upper chip 24 described above. For example, the circuit region 211 of the second lower semiconductor chip 21 may include a second integrated circuit in which the interconnection structure 325 and individual devices 315 are combined. The second integrated circuit may be, for example, the memory circuit described above. For example, the first lower semiconductor chip 20 may include DRAM, while the second lower semiconductor chip 21 may include a NAND flash memory of a different type from that of the first lower semiconductor chip 20. Depending on an example embodiment of the present inventive concept, the upper chip 24 may be electrically connected to the second integrated circuit through the second rear pad 215 and the second lower through-via 210.

Either of the second front pad 213 or the second rear pad 215 may be electrically connected to the interconnection structure 132. It may be understood that the second front pad 213 and the second rear pad 215 have substantially the same characteristics as the first front pad 203 and the first rear pad 205 described above.

It may be understood that the second lower through-via 210 has substantially the same characteristics as the above-described through-substrate via 120.

It may be understood that the second front pad insulating layer 212 and the second rear pad insulating layer 216 have substantially the same characteristics as the above-described first connection pad insulating layer 242.

It may be understood that the second lower semiconductor chip body 217 has substantially the same characteristics as the above-described upper chip body 247.

The interposer chip 22 may be disposed on the substrate 10, and may include a circuit region 221, a third front pad 223, a third rear pad 225, and a third lower through-via 220. As illustrated in FIG. 2C, the interposer chip 22 may further include a third front pad insulating layer 222, a third rear pad insulating layer 226, and an interposer chip body 227.

The interposer chip 22 may be disposed between the substrate 10 and the upper chip 24, and may include a third lower through-via 220 electrically connecting the upper chip 24 and the substrate 10 to each other.

The interposer chip 22 may include a third front pad 223 and a third rear pad 225 opposing each other, and a third lower through-via 220 electrically connecting the third front pad 223 and the third rear pad 225 to each other, and may be disposed between the first lower semiconductor chip 20 and the second lower semiconductor chip 20 so that the third front pad 223 or the third rear pad 225 faces in an upward direction.

The interposer chip 22 may be disposed between the substrate 10 and the upper chip 24, and may include a third lower through-via 220 electrically connecting the first connection pads 243 and the interconnection structure 132 of the substrate 10 to each other.

The interposer chip 22 may be disposed on the interconnection region 130.

For example, an upper surface of each of the first lower semiconductor chip 20, the second lower semiconductor chip 21, and the interposer chip 22 may be substantially on the same level. However, the present inventive concept is not limited thereto.

The interposer chip 22 including the circuit region 221 of the interposer chip 22 might not include an active element or may include an inactive active element.

The inactive active element may be electrically insulated from the third lower through-via 220.

The interposer chip 22 may electrically connect the first connection pads 243 of the upper chip 24 to the interconnection structure 132 of the substrate 10 through the third lower through-via 220.

In addition, it may be understood that the circuit region 221 of the interposer chip 22 has substantially the same characteristics as the circuit region 241 of the upper chip 24 described above.

It may be understood that the third front pad 223 and the third rear pad 225 have substantially the same characteristics as the first front pad 203 and the first rear pad 205.

It may be understood that the third lower through-via 220 has substantially the same characteristics as the above-described through-substrate via 120.

It may be understood that the third front pad insulating layer 222 and the third rear pad insulating layer 226 have substantially the same characteristics as the above-described first connection pad insulating layer 242.

It may be understood that the interposer chip body 227 has substantially the same characteristics as the above-described upper chip body 247.

The chip structure 23 may include a memory chip circuit region 231, a fourth front pad 233, a fourth rear pad 235, and a fourth lower through-via 230. The chip structure 23 may further include a fourth front pad insulating layer 232, a fourth rear pad insulating layer 236, and a chip structure body 237.

The chip structure 23 may include a plurality of memory chips electrically connected to the second lower semiconductor chip 21 through the substrate 10. The chip structure 23 may be disposed on the substrate 10 adjacent to the second lower semiconductor chip 21, and may be electrically connected to the second lower semiconductor chip 21 through the interconnection structure 132.

The chip structure 23 may be a memory device including a plurality of memory chips 23′. For example, the plurality of memory chips 23′ may be NAND flash memories.

As illustrated in FIG. 2A, lower connection bumps 31 disposed on a lower surface of the substrate 10, first intermediate connection bumps 32 disposed on a lower surface of the first lower semiconductor chip 20, second intermediate connection bumps 33 disposed on a lower surface of the second lower semiconductor chip 21, third intermediate connection bumps 34 disposed on a lower surface of the interposer chip 22, and fourth intermediate connection bumps 35 disposed on a lower surface of the chip structure 23 may be further included.

The plurality of connection bumps 31, 32, 33, 34, and 35 may include lower connection bumps 31, first intermediate connection bumps 32, second intermediate connection bumps 33, third intermediate connection bumps 34, and fourth intermediate connection bumps 35. The lower connection bumps 31 may be disposed on a lower surface of the substrate 10. The first intermediate connection bumps 32 may be disposed on a lower surface of the first lower semiconductor chip 20. The second intermediate connection bumps 33 may be disposed on a lower surface of the second lower semiconductor chip 21. The third intermediate connection bumps 34 may be disposed on a lower surface of the interposer chip 22. The plurality of connection bumps 31, 32, 33, 34, and 35 may have a flip-chip connection structure having, for example, a solder ball and a conductive bump or a grid array such as a pin grid array, a ball grid array, and a land grid array. The plurality of connection bumps 31, 32, 33, 34, and 35 may include a metal material, for example, at least one of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C) or an alloy including two or more metals thereof. For example, the plurality of connection bumps 31, 32, 33, 34, and 35 may include tin (Sn) or an alloy (e.g., Sn—Ag—Cu) including tin (Sn).

As illustrated in FIG. 1B, a third lower semiconductor chip 26 overlapping at least a portion of the upper chip 24 in a direction substantially perpendicular to an upper surface of the substrate 10, disposed adjacently to the first lower semiconductor chip 20 in a direction parallel to the upper surface of the substrate 10 (e.g., a y-direction), electrically connected to the substrate 10 and the upper chip 24 may be further included, and the third lower semiconductor chip 26 may be the same type of chip as the first lower semiconductor chip 20.

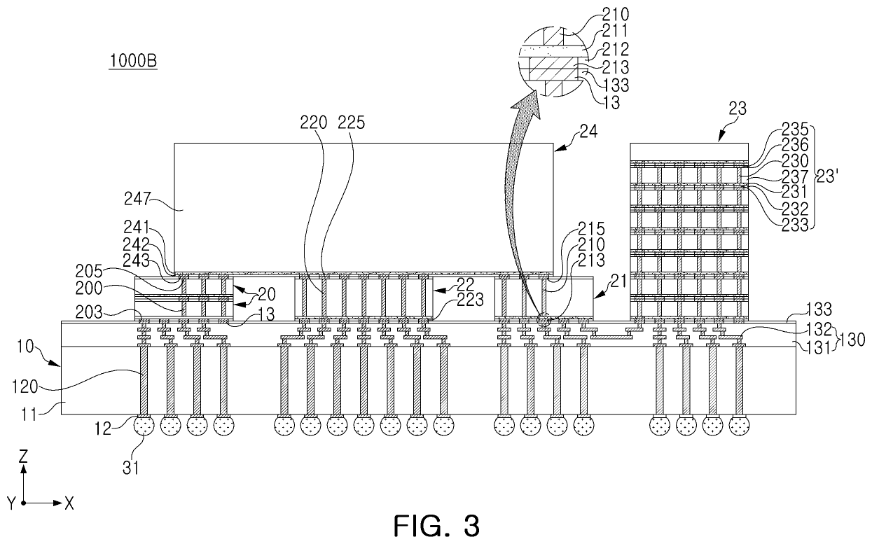

FIG. 3 is a cross-sectional view illustrating a semiconductor package 1000B according to an example embodiment of the present inventive concept.

Referring to FIG. 3, unlike the example embodiment of FIG. 2A, a plurality of lower chips 20, 21, 22, and 23 may be bonded to a substrate 10 so that lower surfaces of the plurality of lower chips 20, 21, 22, and 23 are directly bonded and bonded (e.g., may be referred to as hybrid bonding, direct bonding, or the like) to an upper surface of the substrate 10.

A first front pad 203, a second front pad 213, and a third front pad 223 may be in contact with a connection pad 13 disposed on an upper surface of the interconnection region 130 including the interconnection structure 132. A front pad 233 of the chip structure 23′ may be in contact with the connection pad 13 disposed on the upper surface of the interconnection region 130 including the interconnection structure 132. For example, the connection pad 13 disposed on the upper surface of the interconnection region 130 may be in direct contact with any one of a lower surface of the first front pad 203 and a lower surface of the first rear pad 205, may be in direct contact with any one of a lower surface of the second front pad 213 and a lower surface of the second rear pad, and may be in direct contact with a lower surface of the third frond pad and a lower surface of the third rear pad. For example, the connection pad 13 disposed on the upper surface of the interconnection region 130 may directly contact the third front pad 223.

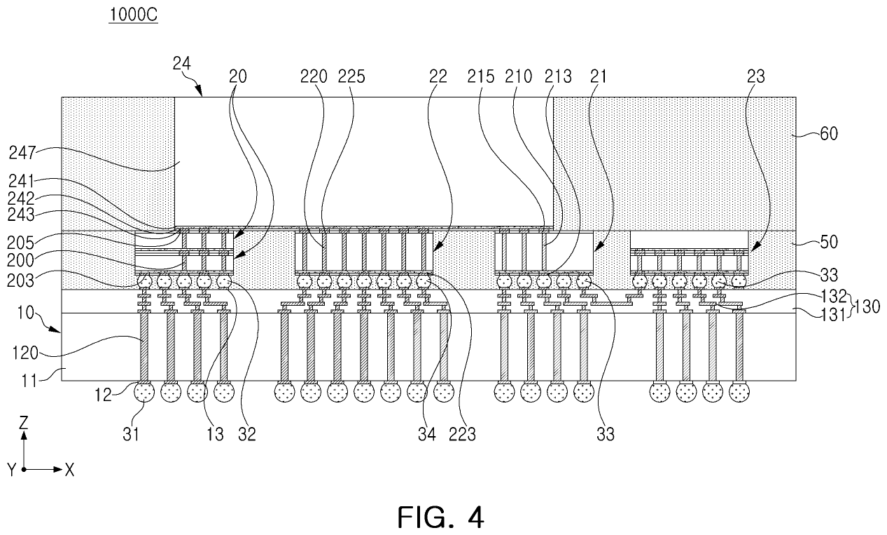

FIG. 4 is a cross-sectional view illustrating a semiconductor package 1000C according to an example embodiment of the present inventive concept.

Referring to FIG. 4, unlike the example embodiment of FIG. 2A, first and second molding members 50 and 60 on a substrate 10 may be included. The first and second molding members 50 and 60 may seal at least a portion of the plurality of chips 20, 21, 22, and 24 on the substrate 10. The first molding member 50 may seal at least a portion of each of the first lower semiconductor chip 20, the second lower semiconductor chip 21, and the interposer chip 22. The first and second molding members 50 and 60 may include, for example, a thermosetting resin such as an epoxy resin, a thermoplastic resin such as polyimide, or prepreg including inorganic fillers and/or glass fibers, Ajinomoto Build-up Film (ABF), FR4, Bismaleimide Triazine (BT), and Epoxy Molding Compound (EMC). The semiconductor package 1000C may further include an underfill resin filling a space between the substrate 10 and the plurality of lower chips 20, 21, and 22. The underfill resin may be molded under-fill (MUF) or capillary under-fill (CUF).

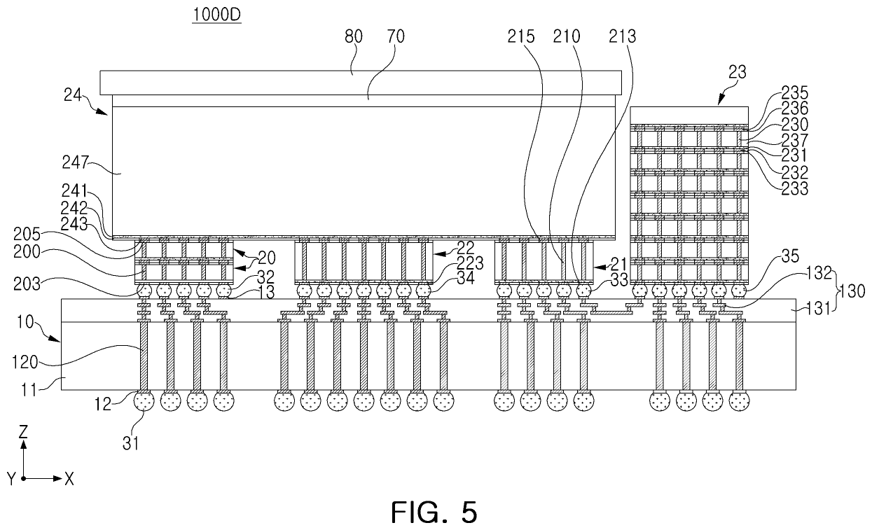

FIG. 5 is a cross-sectional view illustrating a semiconductor package 1000D according to an example embodiment of the present inventive concept.

Referring to FIG. 5, in the example embodiment of FIG. 2A, a heat transfer unit 70 may be disposed on the upper chip 24, and a heat spreader 80 for cooling the semiconductor package 1000D may be included. The heat transfer unit 70 may be formed on an upper portion of the upper chip 24. For example, the heat transfer unit 70 may be formed to cover an upper portion of the upper chip 24. The heat transfer part 70 may be attached on the upper chip 24 by an adhesive. The adhesive may be a thermally conductive adhesive tape, thermally conductive grease, thermally conductive adhesive, or the like. The heat transfer unit 70 may include a conductive material having excellent thermal conductivity. For example, the heat transfer unit 70 may include a metal or a metal alloy including gold (Au), silver (Ag), copper (Cu), iron (Fe), or the like, or a conductive material such as graphite, graphene, and the like. The heat transfer unit 70 may include, for example, a heat sink, a heat slug, a heat transfer material (TIM) layer, or a combination thereof. The heat transfer unit 70 may have a shape different from that shown in the drawings. The heat spreader 80 may be disposed on the heat transfer unit 70 to radiate heat generated by the plurality of chips 20, 21, 22, 23 and 24 externally during operation of the semiconductor package 1000D. The heat spreader 80 may have a plate shape or a polygonal shape covering an upper surface of the heat transfer unit 70. The heat spreader 80 may include a metal such as gold (Au), silver (Ag), or copper (Cu) or a conductive material such as graphite, graphene, and the like.

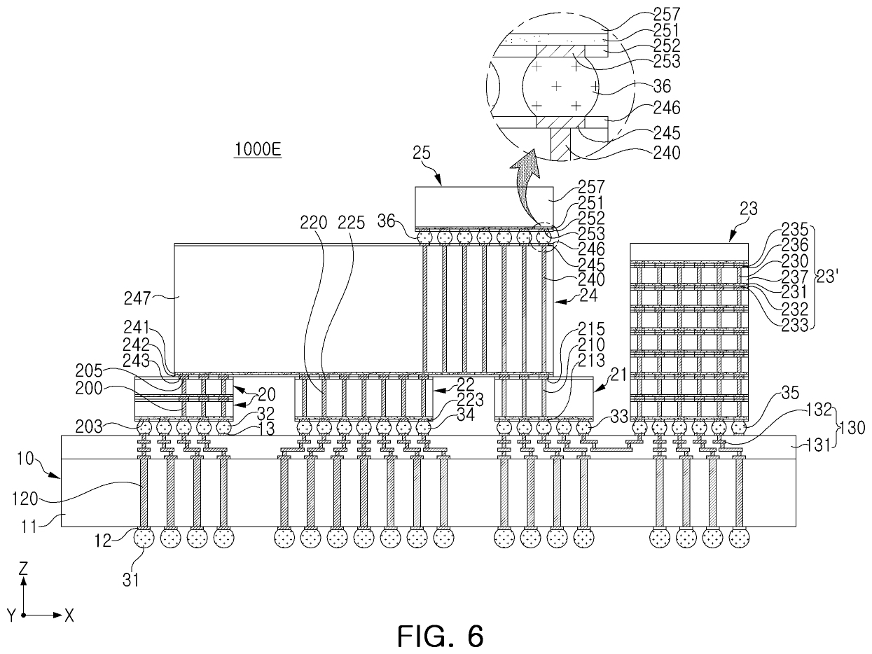

FIG. 6 is a cross-sectional view illustrating a semiconductor package 1000E according to an example embodiment of the present inventive concept.

Referring to FIG. 6, in the example embodiment of FIG. 2A, an uppermost chip 25 disposed on the upper chip 24 and upper connection bumps 36 disposed on a lower surface of the uppermost chip 25 may be included.

The uppermost chip 25 may include a circuit region 251, an uppermost chip connection pad 253, an uppermost chip connection pad insulating layer 246, and an uppermost chip body 257.

The upper chip 24 may further include second connection pads 245 disposed opposite to the first connection pads 243. For example, second connection pads 245 are disposed on a side opposite to the side on which the first connection pads 243 are disposed. The uppermost chip 25 may be disposed on an upper surface of the upper chip 24 and may be electrically connected to the upper chip 24 through the second connection pads 245.

It may be understood that the circuit region 251 of the uppermost chip 25 has substantially the same characteristics as the circuit region 241 of the upper chip 24 described above.

The uppermost chip connection pad 253 may be connected to the second connection pads 245 through the upper connection bumps 36, but an example embodiment thereof is not limited thereto. For example, the uppermost chip connection pad 253 may directly contact the second connection pads 245 without the upper connection bumps 36. In addition, it may be understood that the uppermost chip connection pad 253 has substantially the same characteristics as the first front pad 203 and the first rear pad 205 described above.

It may be understood that the uppermost chip connection pad insulating layer 246 has substantially the same characteristics as the above-described first connection pad insulating layer 242.

It may be understood that the uppermost chip body 257 has substantially the same characteristics as the above-described upper chip body 247.

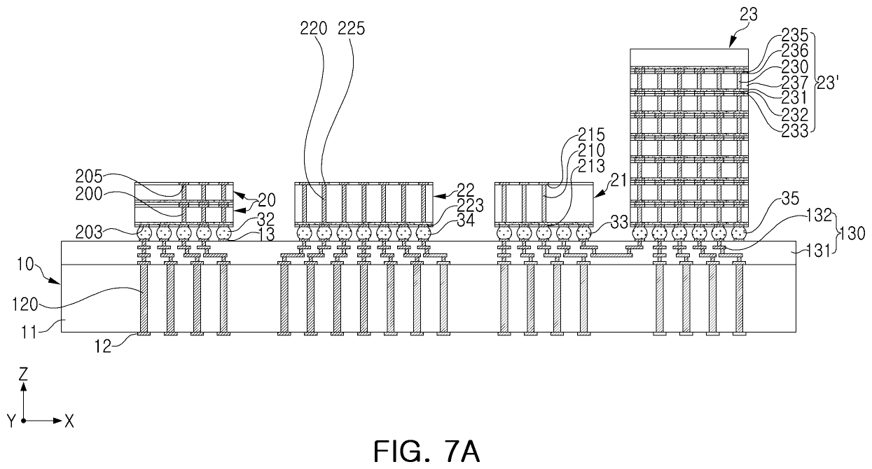

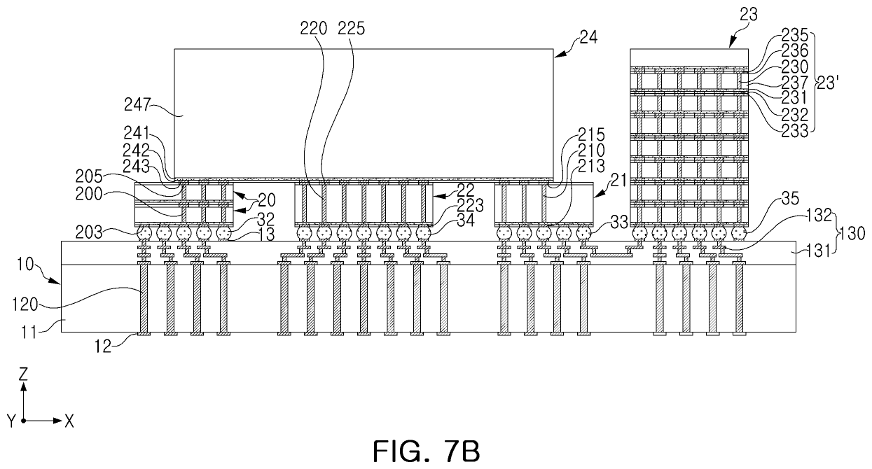

FIGS. 7A and 7B are cross-sectional views sequentially illustrating manufacturing processes of a method of manufacturing the semiconductor package 1000A of FIG. 2A according to an example embodiment of the present inventive concept.

Referring to FIG. 7A, a plurality of lower chips 20, 21, 22, and 23 may be formed on a substrate 10.

First, a plurality of lower chips 20, 21, 22, and 23 may be mounted on the substrate 10. The plurality of lower chips 20, 21, 22, and 23 may be electrically connected to the substrate 10 through first to fourth intermediate connection bumps 32, 33, 34, and 35. Thereafter, according to an example embodiment of the present inventive concept, a first molding member (refer to “50” of FIG. 4) may be formed, and a grinding process, a polishing process, or the like, may be performed.

Referring to FIG. 7B, an upper chip 24 may be formed on the plurality of lower chips 20, 21, and 22.

By performing a thermal compression process, a first connection pad insulating layer 242 and a second rear pad insulating layer 216, bonded to each other, may be bonded to each other, and first connection pads 243 and second rear pads 215, bonded to each other, may be bonded to each other. The thermal compression process may be performed so that the first connection pad insulating layer 242 and the second rear pad insulating layer 216 are first bonded to each other, and then the first connection pads 243 and the second rear pads 215 are bonded to each other. For example, the thermal compression process may be performed so that the first connection pad insulating layer 242 and the second rear pad insulating layer 216 may be bonded to each other in a thermal atmosphere in a range of about 100° C. to about 200° C., and the first connection pads 243 and the second rear pads 215 may be bonded to each other in a thermal atmosphere in a range of about 200° C. to about 300° C. However, the temperature in the thermal atmosphere is not limited to the above-described range (about 100° C. to about 300° C.) and may be variously changed.

Next, referring to FIG. 2A, lower connection bumps 31 such as solder balls, or the like, may be formed on the connection pads 12 of the substrate 10. Accordingly, a semiconductor package 1000A having high performance and high-speed operation may be provided.

As set forth above, according to an example embodiment of the present inventive concept, a semiconductor package having increased reliability may be provided by implementing a channel between semiconductor chips and electrically connecting a semiconductor chip and a substrate to each other.

Herein, a lower side, a lower portion, a lower surface, and the like, are used to refer to a direction toward a mounting surface of the fan-out semiconductor package in relation to cross sections of the drawings, while an upper side, an upper portion, an upper surface, and the like, are used to refer to an opposite direction to the direction. However, these directions are for convenience of explanation, and the claims are not particularly limited by the directions described above.

The meaning of a “connection” of a component to another component in the description includes an indirect connection through an adhesive layer as well as a direct connection between two components. In addition, “electrically connected” conceptually includes a physical connection and a physical disconnection while still being electrically connected (e.g., an indirect electrical connection). It can be understood that when an element is referred to with terms such as “first” and “second”, the element is not limited thereby. They may be used only for a purpose of distinguishing the element from the other elements, and might not limit the sequence or importance of the elements. In some cases, a first element may be referred to as a second element without departing from the spirit and scope of the present inventive concept. Similarly, a second element may also be referred to as a first element.

The term “an example embodiment” used herein does not refer to the same example embodiment, and is provided to emphasize a particular feature or characteristic different from that of another example embodiment. However, example embodiments provided herein are considered to be able to be implemented by being combined in whole or in part one with one another. For example, one element described in a particular example embodiment, even if it is not described in another example embodiment, may be understood as a description related to another example embodiment, unless an opposite or contradictory description is provided therein.

Terms used herein are used only to describe an example embodiment of the present inventive concept rather than limiting the present inventive concept. In this case, singular forms include plural forms unless the context clearly indicates otherwise.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor package, comprising:
a substrate;
a first lower semiconductor chip comprising a first front pad and a first rear pad, opposing each other, a first circuit region disposed between the first front pad and the first rear pad, and a first lower through-via electrically connecting the first rear pad to a first integrated circuit of the first circuit region, wherein the first integrated circuit is electrically connected to the first front pad, wherein the first lower semiconductor chip is disposed on the substrate so that the first front pad or the first rear pad faces in an upward direction;
a second lower semiconductor chip comprising a second front pad and a second rear pad, opposing each other, a second circuit region disposed between the second front pad and the second rear pad, and a second lower through-via electrically connecting the second rear pad to a second integrated circuit of the second circuit region, wherein the second integrated circuit is electrically connected to the second front pad, wherein the second lower semiconductor chip is disposed on the substrate so that the second front pad or the second rear pad faces in the upward direction;
an interposer chip comprising a third front pad and a third rear pad, opposing each other, and a third lower through-via electrically connecting the third front pad and the third rear pad to each other, wherein the interposer chip is disposed between the first lower semiconductor chip and the second lower semiconductor chip so that the third front pad or the third rear pad faces in the upward direction, and is disposed on the substrate; and
an upper chip disposed on the first lower semiconductor chip, the second lower semiconductor chip, and the interposer chip, wherein the upper chip includes first connection pads in contact with the first front pad or the first rear pad facing in the upward direction, the second front pad or the second rear pad facing in the upward direction, and the third front pad or the third rear pad facing in the upward direction.

2. The semiconductor package of claim 1, wherein the first lower semiconductor chip is disposed so that the first rear pad faces in the upward direction, and the upper chip is electrically connected to the first integrated circuit through the first rear pad and the first lower through-via, and
wherein the second lower semiconductor chip is disposed so that the second rear pad faces in the upward direction, and the upper chip is electrically connected to the second integrated circuit through the second rear pad and the second lower through-via.

3. The semiconductor package of claim 1, wherein the upper chip is configured to overlap at least a portion of each of the first lower semiconductor chip, the second lower semiconductor chip, and the interposer chip in a direction substantially perpendicular to an upper surface of the substrate.

4. The semiconductor package of claim 1, wherein the first lower semiconductor chip is provided as a plurality of the first lower semiconductor chips stacked on the substrate, and
wherein the plurality of first lower semiconductor chips are electrically connected to each other through each of the first lower through-vias.

5. The semiconductor package of claim 1, wherein the substrate comprises an interconnection structure, and
wherein the upper chip is electrically connected to the interconnection structure through the third lower through-via of the interposer chip.

6. The semiconductor package of claim 1, wherein the substrate comprises an interconnection structure,
wherein either of the first front pad or the first rear pad, not contacting the first connection pads, is electrically connected to the interconnection structure, and
wherein either of the second front pad or the second rear pad, not contacting the first connection pads, is electrically connected to the interconnection structure.

7. The semiconductor package of claim 1, wherein the interposer chip does not comprise an active element or comprises an inactive active element, and
wherein the inactive active element is electrically insulated from the third lower through-via.

8. The semiconductor package of claim 1, further comprising:
lower connection bumps disposed on a lower surface of the substrate;
first intermediate connection bumps disposed on a lower surface of the first lower semiconductor chip;
second intermediate connection bumps disposed on a lower surface of the second lower semiconductor chip; and
third intermediate connection bumps disposed on a lower surface of the interposer chip.

9. The semiconductor package of claim 1, wherein the substrate comprises an interconnection structure and an interconnection region including the interconnection structure,
wherein a connection pad disposed on an upper surface of the interconnection region is in contact with either of a lower surface of the first front pad or a lower surface of the first rear pad,
wherein the connection pad is in contact with either of a lower surface of the second front pad or a lower surface of the second rear pad, and
wherein the connection pad is in contact with either of a lower surface of the third front pad or a lower surface of the third rear pad.

10. The semiconductor package of claim 1, further comprising:
a chip structure disposed on the substrate and adjacent to the second lower semiconductor chip, wherein the chip structure includes a plurality of memory chips electrically connected to the second lower semiconductor chip through the substrate.

11. The semiconductor package of claim 1, wherein an upper surface of each of the first lower semiconductor chip, the second lower semiconductor chip, and the interposer chip is disposed at substantially a same level as one another.

12. The semiconductor package of claim 1, further comprising:
a first molding member sealing at least a portion of each of the first lower semiconductor chip, the second lower semiconductor chip, and the interposer chip; and
a second molding member disposed on the first molding member, and sealing at least a portion of the upper chip.

13. The semiconductor package of claim 1, wherein the upper chip further comprises second connection pads disposed opposite to the first connection pads, and
wherein the semiconductor package further comprises an uppermost chip disposed on an upper surface of the upper chip to be electrically connected to the upper chip through the second connection pads.

14. The semiconductor package of claim 1, wherein the substrate comprises:
a substrate body having a first surface and a second surface, opposite to the first surface;
an interconnection region including an interconnection structure disposed on the second surface of the substrate; and
a substrate through-via penetrating through the substrate body and electrically connecting a lower connection bump disposed on the first surface of the substrate body to the interconnection structure, and
wherein the first lower semiconductor chip, the second lower semiconductor chip, and the interposer chip are disposed on the interconnection region.

15. The semiconductor package of claim 1, further comprising:
a third lower semiconductor chip overlapping at least a portion of the upper chip in a direction substantially perpendicular to an upper surface of the substrate, and disposed adjacently to the first lower semiconductor chip in a direction parallel to the upper surface of the substrate and electrically connected to the substrate and the upper chip,
wherein the third lower semiconductor chip comprises a chip of a same type as that of the first lower semiconductor chip.

16. A semiconductor package, comprising:
a substrate including an interconnection structure;
an upper chip disposed on the substrate, wherein the upper chip includes first connection pads;
a first lower semiconductor chip disposed between the substrate and the upper chip, wherein the first lower semiconductor chip includes a first rear pad and a first front pad, wherein the first rear pad is connected to the first connection pads, and the first front pad is connected to the interconnection structure;
a second lower semiconductor chip disposed between the substrate and the upper chip, wherein the second lower semiconductor chip includes a second rear pad and a second front pad, wherein the second rear pad is connected to the first connection pads, and the second front pad is connected to the interconnection structure;
an interposer chip disposed between the substrate and the upper chip, wherein the interposer chip includes a lower through-via electrically connecting the first connection pads of the upper chip to the interconnection structure of the substrate; and
a chip structure disposed on the substrate and adjacent to the second lower semiconductor chip, and electrically connected to the second lower semiconductor chip through the interconnection structure.

17. The semiconductor package of claim 16, further comprising:
a heat transfer unit disposed on the upper chip; and
a heat spreader disposed on the heat transfer unit.

18. The semiconductor package of claim 16, wherein the upper chip comprises an application processor, and
wherein the first lower semiconductor chip comprises a DRAM.

19. The semiconductor package of claim 16, wherein the chip structure is a memory device comprising a plurality of memory chips, and
wherein the second lower semiconductor chip is a memory controller configured to control the chip structure.

20. A semiconductor package, comprising:
a substrate;
an upper chip disposed on the substrate;
a first lower semiconductor chip disposed between the substrate and the upper chip, and electrically connected to the substrate;
a second lower semiconductor chip disposed between the substrate and the upper chip, and electrically connected to the substrate; and
an interposer chip disposed between the substrate and the upper chip, wherein the interposer chip includes a through-via electrically connecting the upper chip and the substrate to each other,
wherein the first lower semiconductor chip is electrically connected to the upper chip, wherein a lower surface of the upper chip is disposed on an upper surface of the first lower semiconductor chip, and
wherein the second lower semiconductor chip is electrically connected to the upper chip, wherein a lower surface of the upper chip is disposed on an upper surface of the second lower semiconductor chip.
